(19) United States
(12) Patent Application Publication
(10) Pub. No.: US 2014/0120345 A1
(43) Pub. Date: May 1, 2014

(54) Backing Sheet for Flexographic Printing Plate and Method for Manufacturing the Same

(71) Applicant: FAR EASTERN NEW CENTURY CORPORATION, Taipei (TW)

(72) Inventors: Shu-Chuan Liu, Zhongli City (TW); Chung-Kai Chang, Zhongli City (TW)

(73) Assignee: Far Eastern New Century Corporation, Taipei (TW)

(21) Appl. No.: 13/874,927

(22) Filed: May 1, 2013

(30) Foreign Application Priority Data
Oct. 30, 2012 (TW) 101140113

(51) Int. Cl. B41N 6/00; C09J 7/02; G03F 7/20

(52) U.S. Cl. CPC B41N 6/00; G03F 7/20; C09J 7/02
USPC 428/345; 430/300; 427/487; 427/516; 427/505

(57) ABSTRACT

A backing sheet for a flexographic printing plate and a method for manufacturing the backing sheet are provided. The method includes the steps below. A flexible base plate is provided, and an adhesive is coated thereon. The adhesive includes a resin, a photo initiator and a photocurable compound. A first exposure is then performed so as to convert the adhesive to an adhesive layer, in which the conversion rate of the unsaturated groups of the adhesive layer is in a range of 10 to 65%. The backing sheet manufactured by the above-mentioned method is also provided.

### RELATED APPLICATIONS

This application claims priority to Taiwan Application Serial Number 101140113, filed Oct. 30, 2012, which is herein incorporated by reference.

### BACKGROUND

1. Technical Field

The present disclosure relates to a backing sheet for a flexographic printing plate and a method for manufacturing the backing sheet.

2. Description of Related Art

A flexographic printing plate includes a backing sheet and a photosensitive resin layer having a concave-convex pattern thereon. The backing sheet includes a base plate and an adhesive layer adhering to the base plate and the photosensitive resin layer. After the backing sheet being made, the liquid photosensitive resin layer is formed on the exposed surface of the adhesive layer of the backing sheet. Further, a photolithographic process with exposure and development is conducted to form the photosensitive resin layer having the concave-convex pattern. Finally, the base plate of the flexographic printing plate is attached to a printing cylinder so as to fix the photosensitive layer thereon. The higher adhesive strength and the durability are of the adhesive layer and the base plate and of the adhesive layer and the photosensitive resin layer, the longer is the service life of the flexographic printing plate.

U.S. Pat. No. 3,948,666 disclosed a backing sheet including an adhesive layer and a flexible base plate. The adhesive is a crosslinkable polyester-polyurethane resin. The hydroxyl group and the polyfunctional isocyanate group of the polyester-polyurethane resin are reacted on the base plate so as to adhere thereto. However, after the adhesive is coated, it is required to be processed at 40 to 80° C. for 40 to 120 hours so as to completely dry the surface of the formed adhesive layer.

U.S. Pat. No. 4,269,931 disclosed an adhesive composition. Nevertheless, after the adhesive is coated, it is required to be baked at 120° C. for 2 hours to completely dry out the surface of the formed adhesive layer.

U.S. Pat. No. 5,500,327 disclosed a photosensitive resin element including a support, a thermally hardened layer and a photohardenable layer. The thermally hardened layer and the photohardenable layer are adhered to each other by ultraviolet radiation having a wavelength range of 250 to 500 nm. However, when the exposure time is short, the adhesive strength of the thermally-hardened layer and the photohardenable layer is low. Therefore, a long exposure time is needed in order to enhance the adhesive strength.

Given the above, there is a need for a method for manufacturing a backing sheet with a short process time, which exhibits good adhesive strength and durability of the adhesive layer and the base plate and of the adhesive layer and the photosensitive resin layer, so as to overcome the above-mentioned problems.

### SUMMARY

One aspect of the present disclosure provides a method for manufacturing a backing sheet for a flexographic printing plate, which includes the steps of: providing a flexible base plate; coating an adhesive on the flexible base plate, in which the adhesive includes a resin, a photo initiator, and a photocurable compound having at least two unsaturated groups per molecule, and having a content of 5 to 30 wt % based on the total weight of the adhesive; performing a first exposure of irradiating the adhesive by a first light source to form an adhesive layer, and the adhesive layer adheres to the flexible base plate. The adhesive layer has a conversion rate of the unsaturated groups in a range of 10 to 65%.

Another aspect of the present disclosure provides a backing sheet manufactured by the above-mentioned method.

### BRIEF DESCRIPTION OF THE DRAWINGS

The disclosure may be more fully understood by reading the following detailed description of the embodiment, with reference made to the accompanying drawings as follows:

FIG. 1 is a flowchart of a method for manufacturing a flexographic printing plate according to one embodiment of the present disclosure;

FIG. 2 is a cross-sectional view of a backing sheet according to one embodiment of the present disclosure; and

FIGS. 3A-3C are cross-sectional views of process steps of a method for manufacturing a flexographic printing plate according to one embodiment of the present disclosure.

### DETAILED DESCRIPTION

The present disclosure is described by the following specific embodiments. Those with ordinary skill in the arts can readily understand the other advantages and functions of the present disclosure after reading the disclosure of this specification. The present disclosure can also be implemented with different embodiments. Various details described in this specification can be modified based on different viewpoints and applications without departing from the scope of the present disclosure.

As used herein, the singular forms “a,” “an” and “the” include plural referents unless the context clearly dictates otherwise. Therefore, reference to, for example, an adhesive includes aspects having two or more such adhesives, unless the context clearly indicates otherwise.

Reference will now be made in detail to the embodiments of the present disclosure, examples of which are illustrated in the accompanying drawings. Wherever possible, the same reference numbers are used in the drawings and the description to refer to the same or like parts.

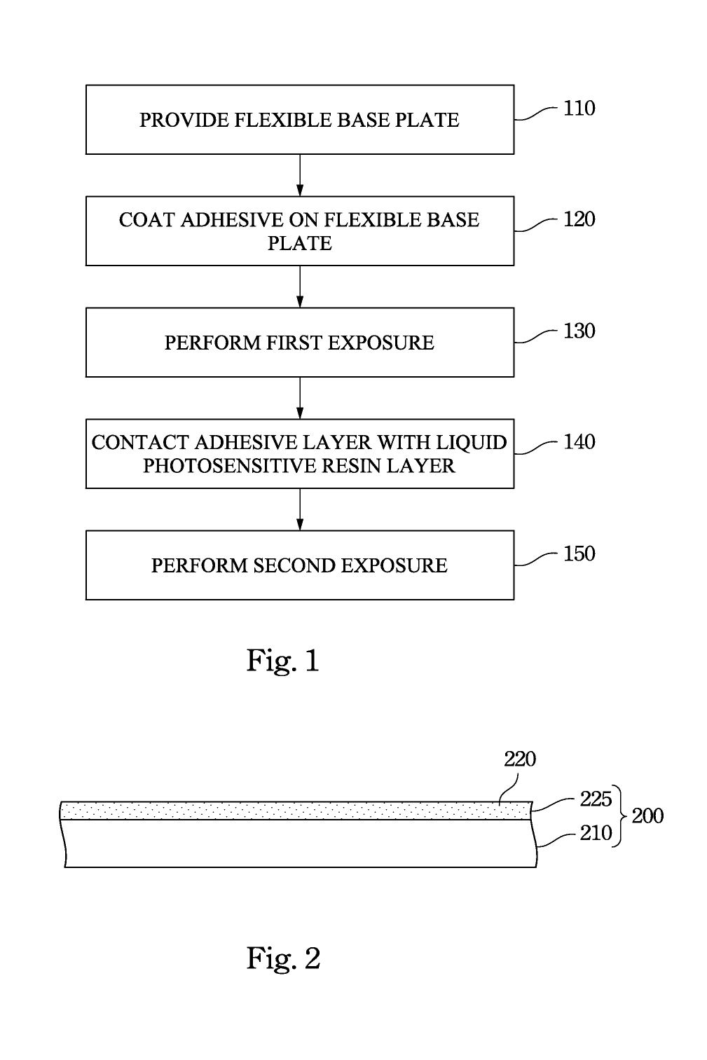

FIG. 1 is a flowchart of a method for manufacturing a flexographic printing plate according to one embodiment of the present disclosure.

In step 110, a flexible base plate 210 is provided, as shown in FIG. 2. The flexible base plate 210 should be a light-penetrable material so as to enable light to pass through it in the subsequent exposure process, so that an adhesive is capable of reacting and adhering to the flexible base plate 210.

In one embodiment, the flexible base plate 210 is selected from the group consisting of polyethylene terephthalate, polyester, polycarbonate, polyolefin, polyamide, polyacrylate, polyvinylchloride, polystyrene and a combination thereof.

In one embodiment, in order to increase the adhesive strength, a surface treatment may be performed on the flexible base plate 210, such as an oxidizing treatment by a strong acid, a corona discharge treatment or a roughening treatment.

In step 120, the adhesive 220 is coated on the flexible base plate 210, as shown in FIG. 2. The adhesive 220 includes a resin, a photo initiator and a photocurable compound. For an example, a wire bar may be used to perform the coating process, but not limited thereto.

The resin is utilized to introduce flexibility to the adhesive layer, which is a polymer having or not having unsaturated groups. In one embodiment, the resin is in an amount of 50 to 90 wt %, based on the total weight of the adhesive, preferably in an amount of 65 to 85 wt %, based on the total weight of the adhesive. In one embodiment, the resin has a weight average molecular weight of 10,000 to 90,000.

In one embodiment, the resin is selected from the group consisting of acrylic resin, epoxy resin, silicone resin, poly(vinyl formal), poly-vinyl butyral (PVB), polyvinyl alcohol, polyester, cellulose esters and a combination thereof.

The photo initiator is used to enable the photocurable compound to perform crosslinking reaction. In one embodiment, the photo initiator is in an amount of 3 to 25 wt %, based on the total weight of the adhesive, preferably in an amount of 5 to 20 wt %, based on the total weight of the adhesive. The above-mentioned amount of the photo initiator can be utilized to increase the rate of photopolymerization of the unsaturated groups of the photocurable compound.

In one embodiment, the photo initiator is selected from the group consisting of 1-hydroxycyclohexyl phenyl ketone, 2,4,6-trimethylbenzoyldiphenylphosphine oxide, 2,2-dimethoxy-2-phenylacetophenone, 2-isopropylthioxanthone, benzophenone, benzoyl peroxide, ethyl 4-dimethylaminobenzoate, 2-hydroxy-2-methylpropiophenone, 4-(4-methylphenylthio)benzophenone, 2-ethylhexyl-4-dimethylaminobenzoate, 2,4-diethylthioxantone and a combination thereof.

The photocurable compound has at least two unsaturated groups per molecule, preferably having 2 to 25 unsaturated groups per molecule, more preferably having 3 to 20 unsaturated groups per molecule. The unsaturated groups are utilized to perform photopolymerization so as to enable the adhesive 220 to adhere to the flexible base plate 210.

When the unsaturated groups per molecule of the photocuable compound are less than 2, the conversion rate of the whole unsaturated groups of the photocuable compound is too high and thus the residual unsaturated groups are too low after performing a first exposure process (i.e., following Step 130), such that the adhesive strength of the adhesive and a photosensitive resin layer is poor. When the unsaturated groups per molecule of the photocuable compound are more than 25, the conversion rate of the unsaturated groups of the photocuable compound is low during the first exposure process (i.e., Step 130) with the same energy so as to affect the adhesive strength of the adhesive and the photosensitive resin layer or of the adhesive and the flexible base plate.

The photocurable compound has an amount of 5 to 30 wt %, based on the total weight of the adhesive, preferably in an amount of 7 to 20 wt %. If the adding amount of the photocurable compound is less than 5%, the amount of the unsaturated groups is low so as to decrease the adhesive strength. If the adding amount of the photocurable compound is higher than 30%, the film surface is hard, brittle and not dry, such that the backing sheet 200 becomes inflexible.

In one embodiment, the photocurable compound is an acrylic monomer or an acrylic oligomer. In one embodiment, the photocurable compound is selected from the group consisting of acrylate, methyl acylate, polyester acrylate, polyester methacrylate, urethane acrylate, urethane methacrylate, epoxy acrylate, epoxy methacrylate and a combination thereof.

In addition, a small amount of additives, such as leveling agents, stabilizers or antioxidants, can be added into the composition of the adhesive according to the requirements. The amount of the additives is less than or equal to 5 wt %, based on the total weight of the adhesive.

In Step 130, the first exposure of irradiating the adhesive 220 by a first light source is performed to form the adhesive layer 225, and the adhesive layer 225 adheres to the flexible base plate 210, as shown in FIG. 2. In this step, the manufacture of the backing sheet 200 has been completed.

The conversion rate of the unsaturated groups of the adhesive layer 225 is in a range of 10 to 65%, preferably in a range of 20 to 60%. If the conversion rate of the unsaturated groups is lower than 10%, the crosslinking density of the adhesive layer 225 is low so as to decrease the adhesive strength. If the conversion rate of the unsaturated groups is higher than 65%, the residual unsaturated groups are less so as to decrease the adhesive strength.

In one embodiment, the first light source is ultraviolet light, visible light, electron beam or X-ray. For an example, the step of performing the first exposure includes irradiating the adhesive by ultraviolet light of 80 mJ/cm² to 200 mJ/cm².

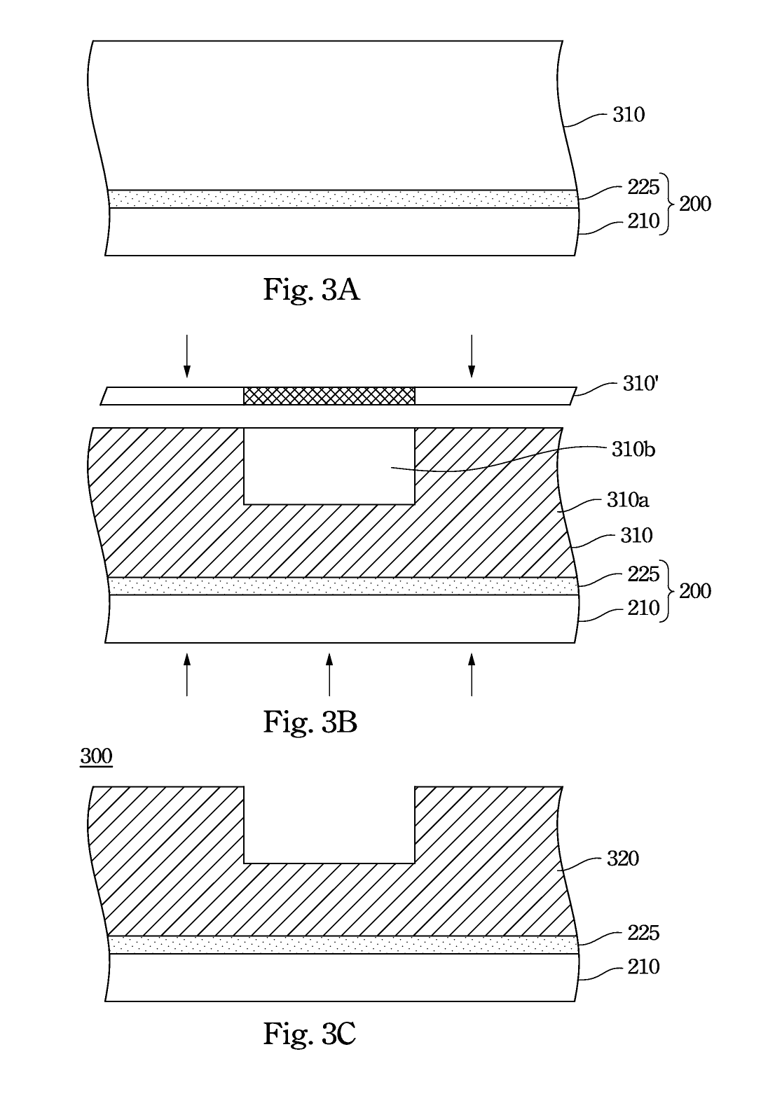

In Step 140, an exposed surface of the adhesive layer 225 is contacted with a liquid photosensitive resin layer 310, as shown in FIG. 3A.

Next, a patterned shielding layer 310′ is provided on the liquid photosensitive resin layer 310 to partially shield the liquid photosensitive resin layer 310, as shown in FIG. 3B.

In Step 150, a second exposure of irradiating the liquid photosensitive resin layer 310 and the adhesive layer 225 by a second light source, as shown in FIG. 3B.

In one embodiment, a bottom exposure process that the illumination light is from the bottom side is performed, and a top exposure process that the illumination light is from the top side is then performed. In the bottom exposure process, a side of the liquid photosensitive resin layer 310 near the adhesive layer 225 performs crosslinking reaction. In the top exposure process, a portion of the liquid photosensitive resin layer 310 which is not shielded by the patterned shielding layer 310′ performs the crosslinking reaction, and another portion of the liquid photosensitive resin layer 310 which is shielded by the patterned shielding layer 310′ does not perform the crosslinking reaction so as to respectively form a crosslinked portion 310a and an uncrosslinked portion 310b, as shown in FIG. 3B.

In one embodiment, the second light source is ultraviolet light, visible light, electron beam or X-ray. For an example, the step of performing the second exposure includes irradiating the liquid photosensitive resin layer 310 and the adhesive layer 225 by ultraviolet light having a wavelength range of 320 nm to 400 nm.

Finally, the uncrosslinked portion 310b is removed so as to form the flexible printing plate 300, as shown in FIG. 3C. For instance, sodium carbonate aqueous solution or alkaline aqueous solution can be utilized to remove the uncrosslinked portion 310b.

In summary, in the embodiments of the present disclosure, a portion of the unsaturated groups of the adhesive performs the crosslinking reaction through the first exposure so as to adhere to the base plate. Next, the residual unsaturated groups perform the crosslinking reaction through the second exposure so as to adhere to the liquid photosensitive resin layer. Therefore, the adhesive strength of the adhesive layer and the base plate and of the adhesive layer and the liquid photosensitive resin layer are good.

Further, in the embodiments of the present disclosure, there is a need for an exposure process to enable the unsaturated groups to perform the crosslinking reaction, and there is no need for long-time heat treatment. Therefore, the embodiments of the present disclosure have the advantages of energy conservation, short process time and low equipment cost.

Another aspect of the present disclosure provides a back sheet 200 for a flexible printing plate, which includes a flexible base plate 210 and an adhesive layer 225, as shown in FIG. 2. The adhesive layer 225 is disposed on the flexible base plate 210, and the adhesive layer 225 includes a resin, a photo initiator and a photocurable polymer. The photocurable polymer is synthesized by polymerizing a photocurable compound. The embodiments of the resin, the photo initiator and the photocurable compound may be the same as the above-mentioned embodiments thereof.

### EMBODIMENTS

The following Examples are provided to illustrate certain aspects of the present disclosure and to aid those of skill in the art in practicing this disclosure. These Examples are in no way to be considered to limit the scope of the disclosure in any manner.

### Embodiment 1

### Flexographic Printing Plates with Various Photocurable Compounds

The manufacturing processes of Examples 1-6 were the same, and the only difference was that various photocurable compounds were respectively used. The preparation of the adhesive, the manufactures of backing sheet and the flexographic printing plate are respectively described below.

### Preparation of Adhesive

### Example 1

15 g of poly-vinyl butyral (tradename: B03-HX, available from ChangChun Petroleum Chemical) was mixed with and dissolved in 30 g of toluene. Next, 2 g of DOUBLEMER 588 as a photocurable compound was added, and 1.25 g of 1-hydroxycyclohexyl phenyl ketone (tradename: IR-184, available from Ciba) as a photoinitiator dissolved in 30 g of methyl ethyl ketone was then added.

The weight ratio for preparing the adhesives of Examples 2-6 was the same as that of Example 1, and the manufactures of the backing sheets and the flexographic printing plates described below were then performed. The compositions and the sources of the photocurable compounds of Examples 1-6 are listed in Table 1.

TABLE 1

| | Number of | | | |
|---|---|---|---|---|
| | unsaturated | | | |
| | groups | Tradename | Composition | Source |
| Exam- | 10 | DOUBLEMER | Aliphatic urethane | Double |
| ple 1 | | 588 | acrylate | Bond |
| Exam- | 12 | DOUBLEMER | Aliphatic urethane | Chemical |
| ple 2 | | 5812 | acrylate | |
| Exam- | 6 | DOUBLEMER | Hexa-functional | |
| ple 3 | | 287 | polyester acrylate | |
| Exam- | 2 | DOUBLEMER | Polyester diacrylate | |
| ple 4 | | 266 | | |
| Exam- | 15 | DOUBLEMER | Polyfunctional | |
| ple 5 | | 2019 | polyester acrylate | |
| Exam- | 3 | U400 | Aliphatic urethane | Bayer |
| ple 6 | | | acrylate/ | |
| | | | Pentaerythritol | |
| | | | tetraacrylate | |

### Manufacture of Backing Sheet

The above-mentioned adhesive was coated on a PET film with a thickness of 125 μm by a wire bar, and the infrared spectrum of the adhesive was then measured. Next, the adhesive was baked at 100° C. for 3 minutes to completely evaporate the solvent. The PET film with the adhesive was placed in a UV processor (Fusion F300S UV system), and an exposure process (UV energy was 80 mJ/cm²) was then performed by a conveyor so as to form the backing sheet having an adhesive layer. The UV lamp was Fusion H-type electrodeless lamp, and the UV energy can be set as 40-350 mJ/cm². The formed adhesive layer has a thickness of 10±2 μm. Afterwards, a cross-cut tape test and an infrared spectrum of the adhesive layer were measured.

The cross-cut tape test was conducted according to ASTM D3359, which tests the adhesive strength of the adhesive layer and the base plate by using a cutting blade and 3M tape. First, the adhesive layer was cut to form a lattice pattern by the cutting blade, and the notch depth reaches the base plate. Next, one end of the tape was fixed in the hand, and the other end thereof was attached on the test surface, and the air bubbles were removed by finger pressure. Subsequently, one end of the attached tape was separated and held by fingers, and then quickly removed with an angle of about 90°. Finally, a visual inspection was employed to check whether or not there was any coating material stuck on the tape, and the result was determined in accordance with Table 2.

TABLE 2

| ASTM | |
|---|---|
| Grade | Result |
| 5B | The edges of the cuts are completely smooth; none of the |
| | squares of the lattice is detached. |
| 4B | Small flakes of the coating are detached at intersections; |
| | less than 5% of the area is affected. |
| 3B | Small flakes of the coating are detached along edges and at |
| | intersections of cuts. The area affected is 5 to 15% of the lattice. |
| 2B | The coating has flaked along the edges and on parts of the |
| | squares. The area affected is 15 to 35% of the lattice. |
| 1B | The coating has flaked along the edges of cuts in large ribbons |
| | and whole squares have detached. The area affected is 35 to 65% |
| | of the lattice. |
| 0B | Flaking and detachment worse than grade 1. |

The conversion rate of the unsaturated groups is utilized to compare the unsaturated groups before the UV treatment (i.e., after coating and before baking) with those after the UV treatment. The calculation method is listed below in Equation (1).

$$Conversion \% = [ 1 - ( \frac{B 2}{B 1} \times \frac{A 1}{A 2} ) ] \times 100 \% \qquad Equation ( 1 )$$

A1: The height of the absorption peak of 1713 cm⁻¹ (C═O) before the UV treatment
A2: The height of the absorption peak of 1713 cm⁻¹ (C═O) after the UV treatment
B1: The height of the absorption peak of 1410 cm⁻¹ (C═C) before the UV treatment
B2: The height of the absorption peak of 1410 cm⁻¹ (C═C) after the UV treatment

### Manufacture of Flexographic Printing Plate

In the example, a printing plate with a thickness of 3.94 mm was formed. First, a negative film was placed on an exposure machine, and a covering film was then covered on the negative film, and liquid photosensitive resin (tradename: MacDermid 36R) was then coated on the covering film. Subsequently, the adhesive layer of the backing sheet covers the flexographic photosensitive resin, and an exposure process was then performed to form a crosslinked portion and an uncrosslinked portion of the flexographic photosensitive resin. After removing the stacked material, the uncrosslinked portion was removed by using 1-3% sodium carbonate aqueous solution to form a photosensitive resin layer having a concave-convex pattern. A UV-A exposure process was performed for 20 minutes, and the photosensitive resin layer was then baked at 60° C. for 30 minutes. Finally, a UV-C exposure process was performed for 5 minutes to form the flexographic printing plate. The adhesive strength of the flexographic printing plate was then measured.

The adhesive strength was measured by scratching the flexographic printing plate by a ballpoint pen (available from Classmates (made in Taiwan), and the pen nib was 0.5 mm) at 45°, and the result was then determined in according with Table 3.

TABLE 3

| Result | Grade | |
|---|---|---|
| No flaking | ⊚ | Excellent |
| Flaking area less than 0.25 cm² | ◯ | |
| Flaking area in a range of 0.26-0.99 cm² | Δ | Fair |
| Flaking area more than 1.00 cm² | X | Poor |

The results of the backing sheets and the flexographic printing plates are listed in Table 4.

TABLE 4

| | Number of | | Cross- | Conversion | |
|---|---|---|---|---|---|
| | unsat- | | cut | rate of | |
| | urated | | tape | unsaturated | Adhesive |
| | groups | Trade name | test | groups (%) | strength |
| Exam- | 10 | DOUBLEMER | 5B | 23 | ⊚ |
| ple 1 | | 588 | | | |
| Exam- | 12 | DOUBLEMER | 5B | 21 | ◯ |
| ple 2 | | 5812 | | | |
| Exam- | 6 | DOUBLEMER | 5B | 30 | ◯ |
| ple 3 | | 287 | | | |
| Exam- | 2 | DOUBLEMER | 5B | 41 | X |
| ple 4 | | 266 | | | |
| Exam- | 15 | DOUBLEMER | 5B | 20 | ◯ |
| ple 5 | | 2019 | | | |
| Exam- | 3 | U400 | 5B | 35 | Δ |
| ple 6 | | | | | |

As shown in Table 4, using different photocurable compounds would significantly affect the adhesive strength under the first exposure process with the same UV energy. When the unsaturated groups per molecule of the photocurable compound were less than 3, the conversion rate of the unsaturated groups was high after the UV treatment and thus the residual unsaturated groups were less, such that the adhesive strength was decreased. Therefore, the unsaturated groups per molecule of the photocurable compound are preferably more than 3.

### Embodiment 2

### Flexographic Printing Plates with Various Contents of Photocurable Compound

Each of the processes for manufacturing the flexographic printing plates of Examples 7-11 was the same as that of Example 1, and the difference was that various proportions by weight of the DOUBLEMER 588 (i.e., photocurable compound) were respectively added. Finally, the adhesive strength of the flexographic printing plates of Examples 7-11 were measured, and the results are listed in Table 5.

TABLE 5

| | | Example 7 | Example 8 | Example 9 | Example 10 | Example 11 |
|---|---|---|---|---|---|---|
| Adhesive | B03-HX (g) | 15 | | | | |
| | DOUBLEMER 588 (g) | 1 (6 wt %) | 2 (10 wt %) | 4 (18 wt %) | 5 (21 wt %) | 8 (29 wt %) |
| | (based on the total weight | | | | | |
| | of the adhesive (wt %)) | | | | | |
| | IR-184 (g) | 0.5 | 1.25 | 2.5 | 3 | 5 |

| | | |
|---|---|---|
| Solvent | Toluene (g) | 30 |
| | Methyl ethyl ketone (g) | 30 |

| | | | | | |
|---|---|---|---|---|---|
| Adhesive strength | X | ◯ | ◯ | X | X |

As shown in Table 5, the adding amount of the photocurable compound would seriously affect the adhesive strength of the printing plate and the adhesive layer. The adding amount of the photocurable compound was preferably in a range of 7 to 20%. If the adding amount of the photocurable compound was lower than 7%, the number of the unsaturated groups was less so as to deteriorate the adhesive strength. If the adding amount of the photocurable compound was higher than 20%, the film surface was hard, brittle and not dry, such that the backing sheet was inflexible and the adhesive strength of the printing plate and the adhesive layer was poor.

### Embodiment 3

### Flexographic Printing Plates under UV Treatment with Various UV energies

Each of the compositions of the adhesives of Examples 12-18 was the same as that of Example 1, and the difference was that various UV energies of the first exposure process were used. Finally, the adhesive strength and the durability (i.e., the adhesive strength test after the treatment of high temperature and high humidity) of the flexographic printing plates of Examples 12-18 were measured, and the results are listed in Table 6.

The durability test was conducted by placing the flexographic printing plate in an oven at high temperature (60° C.) and high humidity (90 RH %) for 336 hours, and then the flexographic printing plate is taken out for the testing of the adhesive strength. Likewise, the grade of the adhesive strength was determined in accordance with Table 3.

TABLE 6

| | | Conversion | | |
|---|---|---|---|---|
| | | rate of | | |
| | UV energy | unsaturated | Adhesive | |
| | (mJ/cm²) | groups (%) | strength | Durability |
| Example 12 | 40 | 13 | ◯ | X |
| Example 13 | 80 | 24 | ⊚ | Δ |
| Example 14 | 100 | 29 | ⊚ | Δ |
| Example 15 | 120 | 33 | ⊚ | ⊚ |
| Example 16 | 180 | 50 | ◯ | ⊚ |
| Example 17 | 250 | 64 | Δ | X |
| Example 18 | 350 | 70 | X | X |

As shown in Table 6, the conversion rate of the unsaturated groups of the photocurable compound increases with the increase of the UV energy. When the conversion rate of the unsaturated groups was in a range of 20 to 60%, the adhesive strength of the printing plate and the adhesive layer was good. In addition, the durability becomes better with the increase of the conversion rate of the unsaturated groups. It may be because high crosslinking density of the adhesive layer would reduce the influence of temperature or humidity on the adhesive layer, and thus the vapor does not easily enter the adhesive layer and destruct the bonding strength of the printing plate and the adhesive layer. However, if the conversion rate of the unsaturated groups was higher than 60%, the residual unsaturated groups are less after forming the backing sheet so as to decrease the adhesive strength.

Although the present disclosure has been described in considerable detail with reference to certain embodiments thereof, other embodiments are possible. Therefore, the spirit and scope of the appended claims should not be limited to the description of the embodiments contained herein.

It will be apparent to those ordinarily skilled in the art that various modifications and variations may be made to the structure of the present disclosure without departing from the scope or spirit of the disclosure. In view of the foregoing, it is intended that the present disclosure cover modifications and variations thereof provided they fall within the scope of the following claims.

What is claimed is:

1. A method for manufacturing a backing sheet for a flexographic printing plate, comprising the steps of:
providing a flexible base plate;
coating an adhesive on the flexible base plate, wherein the adhesive comprises:
a resin;
a photo initiator; and
a photocurable compound having at least two unsaturated groups, and having an content of 5 to 30 wt % based on the total weight of the adhesive;
performing a first exposure of irradiating the adhesive by a first light source to form an adhesive layer, and the adhesive layer adheres to the flexible base plate;
wherein the step of performing the first exposure comprises enabling the adhesive layer to have a conversion rate of the unsaturated groups in a range of 10 to 65%.

2. The method of claim 1, wherein the photocurable compound has 2 to 25 unsaturated groups.

3. The method of claim 1, wherein the photocurable compound is an acrylic monomer or an acrylic oligomer.

4. The method of claim 1, wherein the photocurable compound is selected from the group consisting of acrylate, methyl acylate, polyester acrylate, polyester methacrylate, urethane acrylate, urethane methacrylate, epoxy acrylate, epoxy methacrylate and a combination thereof.

5. The method of claim 1, wherein the photo initiator is selected from the group consisting of 1-hydroxycyclohexyl phenyl ketone, 2,4,6-trimethylbenzoyldiphenylphosphine oxide, 2,2-dimethoxy-2-phenylacetophenone, 2-isopropylthioxanthone, benzophenone, benzoyl peroxide, ethyl 4-dimethylaminobenzoate, 2-hydroxy-2-methylpropiophenone, 4-(4-methylphenylthio)benzophenone, 2-ethylhexyl-4-dimethylaminobenzoate, 2,4-diethylthioxantone and a combination thereof.

6. The method of claim 1, wherein the photo initiator has a content of 3 to 25 wt % based on the total weight of the adhesive.

7. The method of claim 1, wherein the resin is selected from the group consisting of acrylic resin, epoxy resin, silicone resin, poly(vinyl formal), poly-vinyl butyral (PVB), polyvinyl alcohol, polyester, cellulose esters and a combination thereof.

8. The method of claim 1, wherein the first light source is ultraviolet light, visible light, electron beam or X-ray.

9. The method of claim 1, wherein the step of performing the first exposure comprises irradiating the adhesive by ultraviolet light of 80 mJ/cm² to 200 mJ/cm².

10. The method of claim 1, further comprising:
contacting an exposed surface of the adhesive layer with a liquid photosensitive resin layer;
providing a patterned shielding layer on the liquid photosensitive resin layer to partially shield the liquid photosensitive resin layer; and
performing a second exposure of irradiating the liquid photosensitive resin layer and the adhesive layer by a second light source to enable the adhesive layer to adhere to the liquid photosensitive resin layer.

11. The method of claim 10, wherein the second light source is ultraviolet light, visible light, electron beam or X-ray.

12. The method of claim 10, wherein the step of performing the second exposure comprises irradiating the liquid photosensitive resin layer and the adhesive layer by ultraviolet light having a wavelength range of 320 nm to 400 nm.

13. The method of claim 10, wherein the step of performing the second exposure comprises enabling the liquid photosensitive resin layer to form a crosslinked portion and an uncrosslinked portion.

14. The method of claim 1, wherein the flexible base plate is selected from the group consisting of polyethylene terephthalate, polyester, polycarbonate, polyolefin, polyamide, polyacrylate, polyvinylchloride, polystyrene and a combination thereof.

15. A backing sheet for a flexographic printing plate manufactured according to the method of claim 1.
